(19) United States
(12) Patent Application Publication
(10) Pub. No.: US 2025/0268062 A1
(43) Pub. Date: Aug. 21, 2025

(54) Display Device

(71) Applicant: LG Display Co., Ltd., Seoul (KR)

(72) Inventor: SangHyun Lim, Seoul (KR)

(21) Appl. No.: 18/907,914

(22) Filed: Oct. 7, 2024

(30) Foreign Application Priority Data
Feb. 19, 2024 (KR) 10-2024-0023195

(51) Int. Cl. H10K 59/80; H05K 1/18; H10K 59/13

(52) U.S. Cl. CPC H10K 59/872; H05K 1/189; H10K 59/13; H05K 2201/10128

(57) ABSTRACT

A display device includes a cover window, a display panel which includes an active area disposed below the cover window and including a plurality of pixels disposed therein, a first non-active area which encloses the active area, and a bending area which extends from one side of the first non-active area to be bent, a housing which encloses a side surface of the cover window and is spaced apart from the display panel to extend to the bottom of the display panel and a molding member which is disposed in a space in which the housing and the display panel are spaced apart from each other, below the cover window. The molding member is disposed so as to cover a side surface of the display panel and the housing includes a groove disposed in an inner surface opposite to the molding member.

### CROSS-REFERENCE TO RELATED APPLICATION

This application claims the priority of Republic of Korea Patent Application No. 10-2024-0023195 filed on Feb. 19, 2024, which is hereby incorporated by reference in its entirety.

### BACKGROUND

### Field

The present disclosure relates to a display device, and more particularly, to a display device with an improved reliability.

### Description of the Related Art

Currently, as it enters a full-scale information era, a field of a display device which visually expresses electrical information signals has been rapidly developed and studies are continued to improve performances of various display devices such as a thin-thickness, a light weight, and low power consumption.

Among various display devices, a light emitting display device is a self-emitting display device so that a separate light source is not necessary, which is different from the liquid crystal display device. Therefore, the light emitting display device may be manufactured to have light weight and small thickness. Further, since the light emitting display device is driven at a low voltage so that it is advantageous not only in terms of power consumption, but also in terms of color implementation, a response speed, a viewing angle, and a contrast ratio (CR). Therefore, it is expected to be utilized in various fields.

### SUMMARY

An object to be achieved by the present disclosure is to provide a display device in which a moisture permeation defect is minimized or at least reduced to improve the reliability.

Another object to be achieved by the present disclosure is to provide a low-power display device in which damages of components due to heat generated during the operation of the display device is minimized or at least reduced to improve the lifespan.

Objects of the present disclosure are not limited to the above-mentioned objects, and other objects, which are not mentioned above, can be clearly understood by those skilled in the art from the following descriptions.

According to an aspect of the present disclosure, a display device includes a cover window, a display panel which includes an active area disposed below the cover window and including a plurality of pixels disposed therein, a first non-active area which encloses the active area, and a bending area which extends from one side of the first non-active area to be bent, a housing which encloses a side surface of the cover window and is spaced apart from the display panel to extend to the bottom of the display panel and a molding member which is disposed in a space in which the housing and the display panel are spaced apart from each other, below the cover window. The molding member is disposed so as to cover a side surface of the display panel and the housing includes a groove disposed in an inner surface opposite to the molding member.

Other detailed matters of the exemplary embodiments are included in the detailed description and the drawings.

According to an effect by the present disclosure, cracks generated in insulating layers are minimized or at least reduced to minimize the moisture permeation defect to the components of the display device.

According to an effect by the present disclosure, the damage of the components due to heat generated during the operation of the display device may be minimized.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1A is a plan view of a display device according to an exemplary embodiment of the present disclosure before bending a display panel;

FIG. 1B is a rear view of a display device according to an exemplary embodiment of the present disclosure;

FIG. 2A is a cross-sectional view of A-A′ of FIG. 1B according to an exemplary embodiment of the present disclosure;

FIG. 2B is a cross-sectional view of B-B′ of FIG. 1B according to an exemplary embodiment of the present disclosure;

FIG. 3 is a view for explaining a case that a molding member expands in a display device according to an exemplary embodiment of the present disclosure;

FIG. 4 is a cross-sectional view of a display device according to another exemplary embodiment of the present disclosure;

FIG. 5 is a cross-sectional view of a display device according to still another exemplary embodiment of the present disclosure;

FIG. 6 is a view for explaining connection of a display panel and a frame of a display device according to still another exemplary embodiment of the present disclosure;

FIG. 7 is a flowchart for explaining a luminance compensating method of a display device according to still another exemplary embodiment of the present disclosure; and

FIG. 8 is a cross-sectional view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, ‘comprising’ used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

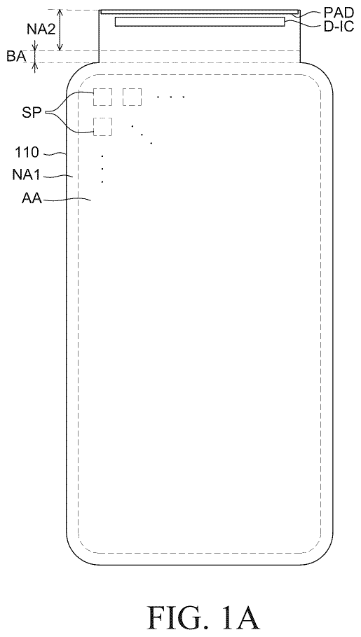

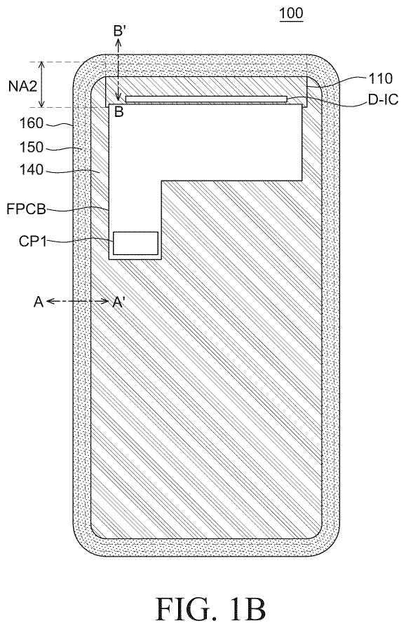

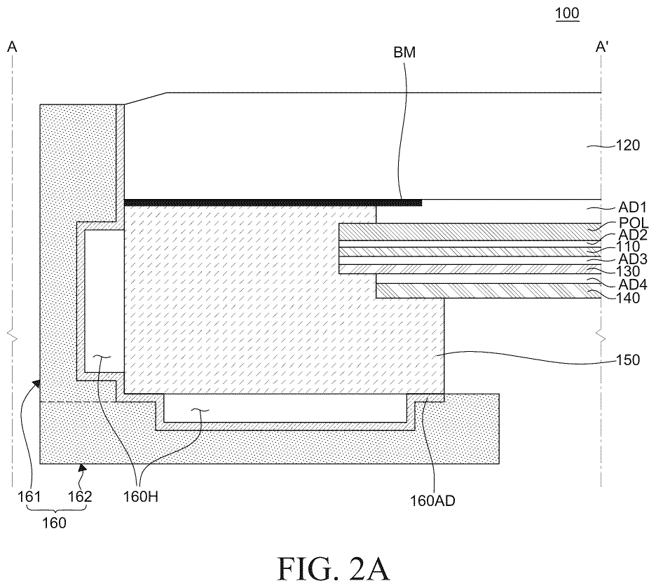

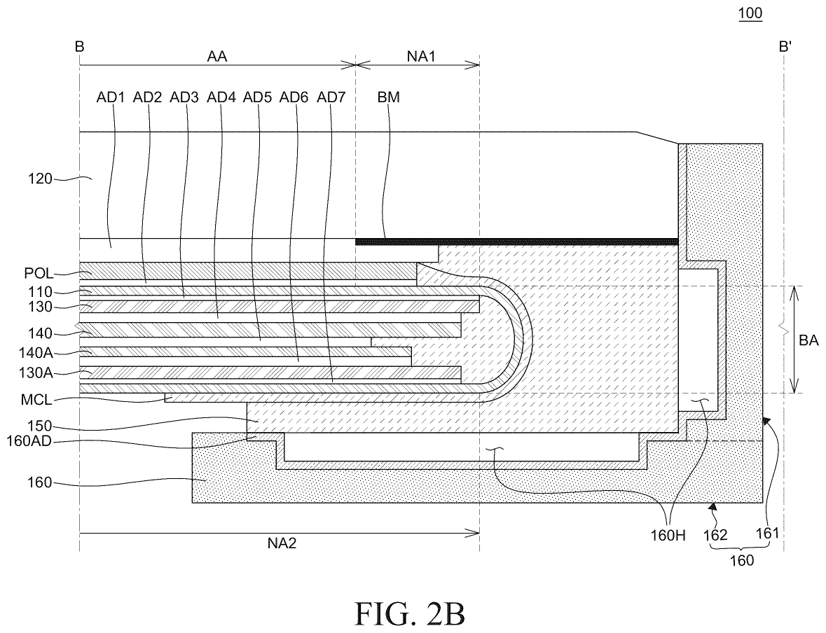

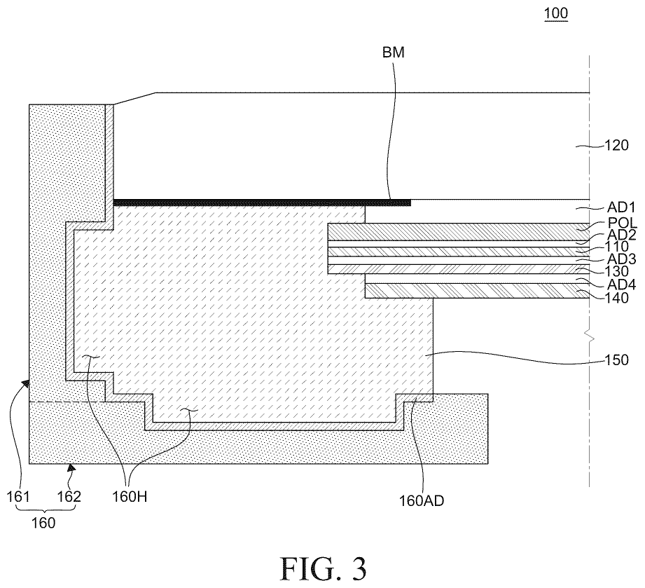

FIG. 1A is a plan view of a display device according to an exemplary embodiment of the present disclosure before bending a display panel. FIG. 1B is a rear view of a display device according to an exemplary embodiment of the present disclosure. FIG. 2A is a cross-sectional view of A-A′ of FIG. 1B according to an exemplary embodiment of the present disclosure. FIG. 2B is a cross-sectional view of B-B′ of FIG. 1B according to an exemplary embodiment of the present disclosure. FIG. 3 is a view for explaining a case that a molding member expands in a display device according to an exemplary embodiment of the present disclosure. In FIGS. 1A to 3, for the convenience of description, among components of a display device 100, a display panel 110, a cover window 120, a back plate 130, a metal plate 140, a molding member 150, and a housing 160 are illustrated. In FIG. 1A, for the convenience of illustration, the hatching of the display panel 110 is omitted.

Referring to FIGS. 1A to 3, a display device 100 according to the present disclosure includes a display panel 110, a cover window 120, a back plate 130, a metal plate 140, a molding member 150, and a housing 160.

The display panel 110 is a panel for displaying images to a user. In the display panel 110, a display element which displays images, a driving element which drives the display element, and wiring lines which transmit various signals to the display element and the driving element may be disposed.

The display element may be defined in different manners depending on the type of the display panel 110. For example, when the display panel 110 is an organic light emitting display panel 110, the display element may be an organic light emitting diode which includes an anode, an organic emission layer, and a cathode. For example, when the display panel 110 is a liquid crystal display panel, the display element may be a liquid crystal display element. Hereinafter, even though the display panel 110 is assumed as an organic light emitting display panel, the display panel 110 is not limited to the organic light emitting display panel.

The display panel 110 includes an active area AA and a non-active area.

The active area AA is an area where images are displayed in the display panel 110. In the active area AA, a plurality of sub pixels SP which configure a plurality of pixels and a driving circuit for driving the plurality of sub pixels SP may be disposed.

The plurality of sub pixels SP are minimum units which configure the active area AA and a display element may be disposed in each of the plurality of sub pixels SP. For example, an organic light emitting diode which includes an anode, an organic emission layer, and a cathode may be disposed in each of the plurality of sub pixels SP, but it is not limited thereto. Further, the driving circuit for driving the plurality of sub pixels SP may include a driving element, a wiring line, and the like. For example, the driving circuit may be configured by a thin film transistor, a storage capacitor, a gate line, and a data line, but is not limited thereto.

The non-active area is an area in which no image is displayed. The non-active area refers to an outer peripheral portion of the display panel 110 which encloses the active area AA. The non-active area may overlap the black matrix BM. In the non-active area, various wiring lines and circuits for driving an organic light emitting diode in the active area AA are disposed. For example, in the non-active area, a link line which transmits signals to the plurality of sub pixels SP and driving circuits of the active area AA or a driving IC (D-IC) such as a gate driver IC or a data driver IC may be disposed, but it is not limited thereto.

The non-active area includes a first non-active area NA1, a bending area BA, and a second non-active area NA2.

The first non-active area NA1 is an area which encloses the active area AA and extends from the active area AA. The bending area BA may extend from one side of the first non-active area NA1 and may be bent. The second non-active area NA2 is an area which extends from the bending area BA to be disposed below the active area.

In the meantime, referring to FIGS. 1A, 1B, and 2B, the first non-active area NA1 and the second non-active area NA2 are disposed on the same plane as the active area AA or disposed to be parallel to the active area AA and maintain a flat state. For example, the first non-active area NA1 may be disposed to be flat on the same plane as the active area AA and the second non-active area NA2 may be disposed below the active area AA to be parallel to the active area AA and be flat. Therefore, the active area AA, the first non-active area NA1, and the second non-active area NA2 may be referred to as non-bending areas, but are not limited thereto.

Referring to FIGS. 1A and 1B, the driving IC D-IC is disposed in the second non-active area NA2. The driving IC D-IC may supply a data signal to the plurality of sub pixels SP. For example, the driving IC D-IC samples and latches the data signal supplied from the timing controller in response to a data timing control signal supplied from the timing controller to convert the data signal into a gamma reference voltage and output the converted gamma reference voltage. The driving IC D-IC may output a data signal through the plurality of data lines. In the meantime, the driving IC D-IC is disposed on one side of the display panel 110 in a chip on panel (COP) manner to be connected to the display panel 110 or is disposed in a separate flexible film to be connected to the display panel 110 in a chip on film (COF) manner. In the display device 100 according to the exemplary embodiment of the present disclosure, it is assumed that the driving IC D-IC is disposed in the COP manner, but it is not limited thereto.

In the second non-active area NA2 in which the driving IC D-IC is disposed, a pad unit PAD is disposed. The pad unit PAD may supply various signals and voltages to the driving IC D-IC and the plurality of sub pixels SP. For example, the pad unit PAD may include a plurality of pads disposed on the display panel 110, but is not limited thereto.

A flexible circuit board FPCB may be connected to the pad unit PAD. The flexible circuit board FPCB may supply a data signal to the driving IC D-IC through the pad unit PAD. The flexible circuit board FPCB includes a first connection unit CP1 to receive the data signal. For example, a controller which supplies a control signal to the display panel 110 and a frame in which the controller is disposed may be disposed below the display panel 110. A second connection unit may be disposed in the frame to be connected to the first connection unit CP1. Therefore, the flexible circuit board FPCB may be connected to the controller by means of the connection of the first connection unit CP1 and the second connection unit and supply a control signal to the driving IC D-IC and the display panel 110, but is not limited thereto.

Referring to FIGS. 1A and 1B, as the display panel 110 is bent, the driving IC D-IC disposed in the second non-active area NA2 is disposed below the active area AA. For example, the driving IC D-IC and the flexible circuit board FPCB connected to the pad unit PAD of the display panel 110 move to the rear surface of the display panel 110 and overlap the active area AA. Therefore, as seen from the top of the display panel 110, circuit elements, such as the driving IC D-IC and the flexible circuit board FPCB may not be visible. Accordingly, a size of the non-active area which is visible from the top of the display panel 110 is reduced to implement a narrow bezel.

The display panel 110 may include a substrate, a pixel unit, an encapsulation layer, and the like.

The substrate is a base member which supports various components of the display panel 110 and may be configured by an insulating material. The substrate is formed of a plastic material having flexibility. For example, the substrate may be formed of a plastic material, such as polyimide (PI), but is not limited thereto.

The pixel unit includes a plurality of organic light emitting diodes and a circuit for driving the organic light emitting diodes. The pixel unit may be disposed so as to correspond to the active area AA.

In the meantime, the display panel 110 may be configured by a top emission type or a bottom emission type, depending on an emission direction of light which is emitted from the organic light emitting diode.

According to the top emission type, light emitted from the organic light emitting diode is emitted to an upper portion of the substrate on which the organic light emitting diode is formed. In the case of the top emission type, a reflective layer may be formed below the anode to allow the light emitted from the organic light emitting diode to travel above the substrate, that is, toward the cathode.

According to the bottom emission type, light emitted from the organic light emitting diode is emitted to a lower portion of the substrate on which the organic light emitting diode is formed. In the case of the bottom emission type, the anode may be formed only of a transparent conductive material and the cathode may be formed of the metal material having a high reflectance to allow the light emitted from the organic light emitting diode to travel below the substrate.

Hereinafter, the description will be made under the assumption that the display device 100 according to the exemplary embodiment of the present disclosure is a top emission type, but it is not limited thereto.

The encapsulation layer is disposed so as to cover the pixel unit. The encapsulation layer seals the organic light emitting diode of the pixel unit. The encapsulation layer may protect the organic light emitting diode of the pixel unit from moisture, oxygen, impact, or the like of the outside. The encapsulation layer may be formed by alternately laminating a plurality of inorganic layers and a plurality of organic layers. For example, the inorganic layer may be formed of an inorganic material such as silicon nitride (SiNx), silicon oxide (SiOx), and aluminum oxide (AlOx) and the organic layer may be formed of epoxy-based or acrylic-based polymer, but they are not limited thereto.

Referring to FIGS. 2A to 3, the cover window 120 is disposed on the front surface of the display panel 110. The cover window 120 may be a component which is exposed to the outer periphery of the display device 100 and protect the display device 100 from external shock or scratches. Further, the cover window 120 may protect the display device 100 from moisture permeating from the outside. The cover window 120 may be formed of a glass or a plastic material having a flexibility, but is not limited thereto.

A black matrix BM is disposed below the cover window 120. The black matrix BM may be disposed along the circumference of the cover window 120 at the other periphery of the cover window 120. At this time, the area in which the black matrix BM is disposed may correspond to the first non-active area NA1. The black matrix BM may be formed of a material having a low permeability. Therefore, the black matrix BM may suppress various components disposed below the first non-active area NA1 from being visible to the outside. Further, the black matrix BM is formed of a material having a conductivity to discharge static electricity of the cover window 120.

The black matrix BM may be configured by chrome (Cr), graphite, or resin including conductive particles. Here, the resin may be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto. Further, the conductive particle may also be formed of any one of molybdenum (Mo), chrome (Cr), titanium (Ti), nickel (Ni), neodymium (Nd), copper (Cu), and an alloy of silver (Ag) and magnesium (Mg), but is not limited thereto.

Referring to FIGS. 2A to 3, a polarizer POL is disposed between the display panel 110 and the cover window 120. The polarizer POL may be disposed on the front surface of the display panel 110. The polarizer POL selectively transmits light to reduce the reflection of external light which is incident onto the display panel 110. Specifically, the display panel 110 includes various metal materials applied to the semiconductor element, the wiring line, and the organic light emitting diode. Therefore, the external light incident onto the display panel 110 may be reflected from the metal material so that the visibility of the display device 100 may be reduced due to the reflection of the external light. In contrast, when the polarizer POL is disposed, the polarizer POL suppresses the reflection of the external light so that the outdoor visibility of the display device 100 may be increased. However, the polarizer POL may be omitted depending on an implementation example of the display device 100, but it is not limited thereto.

A first adhesive layer AD1 is disposed between the polarizer POL and the cover window 120 and a second adhesive layer AD2 is disposed between the polarizer POL and the display panel 110. The first adhesive layer AD1 may bond the cover window 120 and the polarizer POL and the second adhesive layer AD2 may bond the polarizer POL and the display panel 110. As a result, the first adhesive layer AD1 and the second adhesive layer AD2 may bond the display panel 110 and the cover window 120. The first adhesive layer AD1 and the second adhesive layer AD2 may be formed as transparent adhesive layers so that an image of the display panel 110 is visible. For example, the first adhesive layer AD1 and the second adhesive layer AD2 may be formed of optical clear adhesives (OCA), but are not limited thereto.

The back plate 130 is disposed below the display panel 110. The back plate 130 may be disposed so as to support the display panel 110. For example, when the substrate of the display panel 110 is formed of a plastic material such as polyimide, due to the flexible property, a separate component for protecting the substrate may be necessary. Therefore, a support substrate which is formed of glass is disposed below the substrate to perform a manufacturing process of the display device 100. The support substrate may be separated to be released after completing the manufacturing process. However, a component for supporting the substrate is necessary even after releasing the support substrate, so that the back plate 130 for supporting the substrate may be disposed below the display panel 110.

The back plate 130 may include a plastic material. For example, the back plate 130 may be formed of a plastic thin film formed of polyimide (PI), polyethylene naphthalate (PEN), polyethylene terephthalate (PET), or a combination of the polymers.

A third adhesive layer AD3 is disposed between the display panel 110 and the back plate 130. The third adhesive layer AD3 may bond the display panel 110 and the back plate 130. The third adhesive layer AD3 may be formed of a pressure sensitive adhesive (PSA), but is not limited thereto.

The metal plate 140 is disposed below the back plate 130. The metal plate 140 may protect the components of the display device 100 from external shocks. Further, the metal plate 140 serves as an earth to suppress the static electricity entering the display device 100 or easily discharge residual charges accumulated in the display device 100 to the outside. Further, the metal plate 140 easily discharges heat generated in the display device 100 to the outside. The metal plate 140 may be formed of a metal material having excellent thermal conductivity, electrical conductivity, and mechanical rigidity. For example, the metal plate 140 may be configured by copper (Cu) or stainless steel (SUS), but is not limited thereto.

A fourth adhesive layer AD4 may be disposed between the back plate 130 and the metal plate 140. The fourth adhesive layer AD4 may bond the back plate 130 and the metal plate 140 to each other. The fourth adhesive layer AD4 may be formed of a pressure sensitive adhesive (PSA), but is not limited thereto.

Referring to FIG. 2B, an additional back plate 130A and an additional metal plate 140A are disposed below the metal plate 140 corresponding to the bending area BA.

The additional back plate 130A and the additional metal plate 140A may supplement the rigidity of the second non-active area NA2 of the display panel 100 disposed in the second non-active area. In the meantime, the additional back plate 130A and the additional metal plate 140A may be disposed so as not to overlap (e.g., non-overlapping) the bending area BA. Therefore, the thicknesses of the configurations disposed in the bending area BA are minimized and a neutral plane of the bending area BA is easily controlled to ensure the flexibility of the bending area.

Referring to FIG. 2B, a fifth adhesive layer AD5 is disposed between the metal plate 140 and the additional metal plate 140A and a sixth adhesive layer AD6 is disposed between the additional metal plate 140A and the additional back plate 130A. The fifth adhesive layer AD5 may bond between the metal plate 140 and the additional metal plate 140A and the sixth adhesive layer AD6 may bond between the additional metal plate 140A and the additional back plate 130A. For example, the fifth adhesive layer AD5 and the sixth adhesive layer AD6 may be formed of a pressure sensitive adhesive (PSA), but are not limited thereto.

The second non-active area NA2 of the display panel 110 is disposed below the additional back plate 130A. Further, a seventh adhesive layer AD7 is disposed between the additional back plate 130A and the second non-active area NA2 of the display panel 110. The seventh adhesive layer AD7 may bond between the additional back plate 130A and the second non-active area NA2 of the display panel 110. For example, the seventh adhesive layer AD7 may be formed of a pressure sensitive adhesive (PSA), but is not limited thereto.

The molding member 150 seals the cover window 120, the display panel 110, the back plate 130, and the metal plate 140. Specifically, the molding member 150 may be disposed so as to enclose a lower portion of the cover window 120, a side surface of the display panel 110, a side surface of the back plate 130, a side surface and a part of a bottom surface of the metal plate 140. The molding member 150 may suppress the permeation of the moisture or oxygen into the display device 100. Further, the molding member 150 may protect components of the display device 100 and relieve shocks applied to the display device 100.

For example, the molding member 150 is formed by a process of removing a mold, after filling and curing the mold which is disposed to enclose a side surface of the cover window 120 and expose a side surface of the display panel 110, a side surface of the back plate 130, a side surface and a part of a bottom surface of the metal plate 140 with a material for forming the molding member 150. However, the method of forming the molding member 150 is not limited thereto.

The molding member 150 may be formed of one or more materials of acrylic resin, epoxy resin, phenolic resin, polyamides resin, polyimides resin, unsaturated polyesters resin, polyphenylene resin, polyphenylenesulfides resin, and benzocyclobutene, but is not limited thereto.

The housing 160 is disposed on a side surface of the cover window 120 and a side surface and a bottom surface of the molding member 150. The housing 160 is disposed to be spaced apart from the display panel 110 while enclosing a side surface of the cover window 120 and extends to a lower portion of the display panel 110. Therefore, the housing 160 may be configured to cover the cover window 120 and the molding member 150 and protect the cover window 120 and the molding member 150.

An inner surface of the housing 160 is bonded to the molding member 150. A part of the inner surface of the housing 160 is bonded to the molding member 150. The housing 160 is bonded to the molding member 150 to cover a side surface and a bottom surface of the molding member 150. For example, a housing adhesive layer 160AD may be disposed between the inner surface of the housing 160 and the molding member 150. The housing adhesive layer 160AD is disposed between the inner surface of the housing 160 and the molding member 150 to bond the inner surface of the housing 160 and the molding member 150, but is not limited thereto.

The housing 160 may be formed of a material having a predetermined rigidity to protect the side surfaces of the cover window 120 and the molding member 150. For example, the housing 160 may be formed of a plastic formed by any one of polyimide (PI), polyethylene naphthalate (PEN), polyethylene terephthalate (PET) and a combination of the polymers or a metal such as copper (Cu) or stainless steel (SUS), but is not limited thereto.

The housing 160 includes a first part 161 and a second part 162. The first part 161 is a part which extends downwardly from the side surface of the cover window 120 in the housing 160. The first part 161 may be opposite to the side surface of the molding member 150. The second part 162 is a part which extends to the inside of the housing 160 from an end portion of the first part 161 in the housing 160. The second part 162 may be opposite to the bottom surface of the molding member 150. In the meantime, the first part 161 and the second part 162 may be integrally formed, but are not limited thereto.

Referring to FIGS. 2A to 3, a groove 160H which is opposite to the molding member 150 is disposed in the housing 160. The groove 160H is disposed on the inner surface of the housing 160 and is disposed to be opposite to the molding member 150. The groove 160H may be a part of the inner surface of the housing 160 in which the thickness is partially reduced. The groove 160H may be disposed along an outer periphery of the molding member on the inner surface of the housing 160.

At this time, the inner surface of the housing 160 in which the groove 160H is not disposed is disposed to be in contact with the molding member 150. For example, the part of the inner surface of the housing 160 in which the groove 160H is disposed is spaced apart from the molding member 150 and a part of the inner surface of the housing 160 in which the groove is not disposed may be bonded to the molding member 150 by means of the housing adhesive layer 160AD.

In the meantime, the groove 160H may be a space configured to accommodate the molding member 150 when a volume of the molding member 150 expands. Therefore, as illustrated in FIGS. 2A and 2B, the groove 160H may be spaced apart from the molding member 150 when the molding member 150 does not expand. Further, as illustrated in FIG. 3, when the molding member 150 expands, the molding member 150 may be filled in the groove 160H of the housing 160.

Referring to FIGS. 2A to 3, the groove 160H may be disposed in each of the first part 161 and the second part 162. The grooves 160H may be disposed in the first part 161 and the second part 162 to be opposite to the side surface and the bottom surface of the molding member 150, respectively. For example, the grooves 160H are disposed to be opposite to the side surface and the bottom surface of the molding member 150 so that for all the cases when the molding member 150 expands toward the side portion or the bottom, the groove 160H may be configured to accommodate the molding member 150. However, it is not limited thereto.

In the display device, a separate cover unit may be disposed below the cover window so as to protect side surfaces of the components of the display device, such as a display panel. However, when a separate cover unit is disposed, in order to minimize or at least reduce the interference between the display panel and the cover unit, the cover unit is coupled to be spaced apart from the display panel with a predetermined distance. Therefore, in the display device in which a separate cover unit is disposed below the cover window, it is difficult to implement a narrow bezel due to the space between the display panel and the cover unit.

In the display device 100 according to the exemplary embodiment of the present disclosure, a molding member 150 which seals the components of the display device 100 is disposed below the cover window 120 to minimize or at least reduce the size of the bezel area.

Specifically, the display device 100 according to the exemplary embodiment of the present disclosure seals the components of the display device 100 by means of the molding member 150. The molding member 150 may be disposed so as to enclose a side surface of the display panel 110, a side surface of the back plate 130, and a side surface of the metal plate 140 from a lower portion of the cover window 120 and cover a part of the bottom surface of the metal plate 140. That is, the molding member 150 is integrally formed with the display device 100 while directly enclosing the components of the display device 100 so that a separate configuration, such as a cover unit for protecting the components of the display device 100, will be omitted. Therefore, a separate space for minimizing or at least reducing the interference between a separate configuration, such as a cover unit and components of the display device 100 may also be omitted so that the size of the first non-active area NA1, that is, the bezel area, may be minimized or at least reduced. Accordingly, in the display device 100 according to the exemplary embodiment of the present disclosure, a molding member 150 which seals the components of the display device 100 is disposed below the cover window 120 to minimize or at least reduce the size of the bezel area and implement a narrow bezel.

In the meantime, in the display device 100 according to the exemplary embodiment of the present disclosure, the molding member 150 is formed of resin so that the molding member 150 may buffer an external impact on the components of the display device 100 sealed by the molding member 150, such as the display panel 110. Therefore, in the display device 100 according to the exemplary embodiment of the present disclosure, an additional effect of buffering the external impact applied to the display device 100 by the molding member 150 formed of resin may be provided.

In the meantime, in the display device, a housing which covers and protects the cover window and the molding member may be attached to the outsides of the cover window and the molding member. At this time, a volume of the molding member which is formed of resin may expand as the temperature increases. However, the housing is attached to the outside of the molding member so that when the volume of the molding member expands, the molding member expands toward the side surface of the display panel to pressurize the side surface of the display panel. Therefore, the side surface of the display panel is pressurized to cause the cracks on insulating layers disposed on the display panel. Further, moisture permeates the components disposed on the display panel due to the cracks of the insulating layers, which causes the defect of the display panel so that there is a problem in that the reliability of the display device is degraded.

In the display device 100 according to the exemplary embodiment of the present disclosure, the groove 160H is disposed on the inner surface of the housing 160 opposite to the molding member 150 to improve the reliability of the components disposed on the display panel 110.

Specifically, in the display device 100 according to the exemplary embodiment of the present disclosure, the groove 160H is disposed on the inner surface of the housing 160 opposite to the molding member 150. The groove 160H is a part of the inner surface of the housing 160 opposite to the molding member 150 in which the thickness is partially reduced. Further, the inner surface of the housing 160 in which the groove 160H is not disposed is disposed to be in contact with the molding member 150. Therefore, even though the molding member 150 expands as the temperature increases, the molding member 150 may be filled in the groove 160H of the housing 160. As the molding member 150 is filled in the groove 160H, the expansion of the molding member 150 toward the side surface of the display panel 110 may be reduced and the pressurization of the molding member 150 to the side surface of the display panel 110 may be minimized or at least reduced. Therefore, even though the molding member 150 expands as the temperature increases, the molding member 150 is filled in the groove 160H so that the pressure applied to the display panel 110 may be minimized or at least reduced and the crack generated in the insulating layers disposed on the display panel 110 caused by the pressure may be also minimized or at least reduced. Therefore, the reliability of the components disposed on the display panel 110 may be improved. Accordingly, in the display device 100 according to the exemplary embodiment of the present disclosure, the groove 160H is disposed on the inner surface of the housing 160 opposite to the molding member 150 to improve the reliability of the components disposed on the display panel 110.

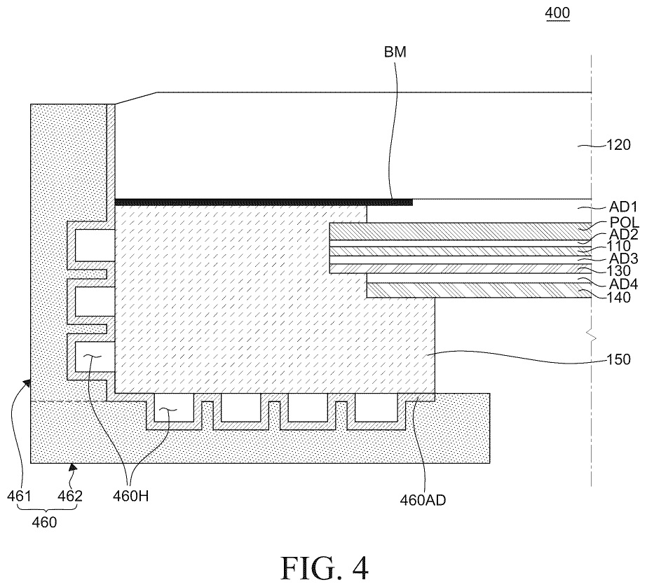

FIG. 4 is a cross-sectional view of a display device according to another exemplary embodiment of the present disclosure. A display device 400 of FIG. 4 is the same as the display device 100 of FIGS. 1A to 3 except that a plurality of grooves 460H is disposed in a housing 460 so that a redundant description will be omitted.

Referring to FIG. 4, in a display device 400 according to another exemplary embodiment of the present disclosure, a plurality of grooves 460H are disposed in the housing 460. At this time, a plurality of grooves 460H is disposed in each of a first part 461 and a second part 462 of the housing 460. In the meantime, even though in FIG. 4, it is illustrated that three grooves 460H are disposed in the first part 461 and four grooves 460H are disposed in the second part 462, the number of grooves 460H disposed in each of the first part 461 and the second part 462 may vary depending on the design, but is not limited thereto.

Referring to FIG. 4, the inner surface of the housing 460 in which the groove 460H is not disposed is disposed to be in contact with the molding member 150. For example, the part of the inner surface of the housing 460 in which the groove 460H is disposed is spaced apart from the molding member 150 and a part of the inner surface of the housing 460 in which the groove is not disposed may be bonded to the molding member 150 by means of a housing adhesive layer 460AD.

In the display device 400 according to another exemplary embodiment of the present disclosure, a plurality of grooves 460H are disposed in the housing 460 so that the adhesive strength between the housing 460 and the molding member 150 may be improved.

Specifically, in the display device 400 according to another exemplary embodiment of the present disclosure, a plurality of grooves 460H are disposed in the housing 460. A plurality of grooves 460H are disposed in each of a first part 461 and a second part 462 of the housing 460. In the meantime, the part of the inner surface of the housing 460 in which the groove 460H is disposed is spaced apart from the molding member 150. The part of the inner surface of the housing 460 in which the groove 460H is not disposed, for example, an inner surface of the housing 460 corresponding to an area between the plurality of grooves 460H, may be bonded to the molding member 150 by means of the housing adhesive layer 460AD. At this time, when the number of grooves 460H increases, the area of the inner surface of the housing 460 corresponding to an area between the plurality of grooves 460H may be relatively increased, as compared with the smaller number of grooves 460H. That is, when the plurality of grooves 460H are disposed in the housing 460, an area of the inner surface of the housing 460 corresponding to an area between the plurality of grooves 460H may be increased. Therefore, an area of the inner surface of the housing 460 which is attached to the molding member 150 by the housing adhesive layer 460AD is increased and the adhesive strength between the housing 460 and the molding member 150 may be improved. Accordingly, in the display device 400 according to another exemplary embodiment of the present disclosure, a plurality of grooves 460H is disposed in the housing 460 so that the adhesive strength between the housing 460 and the molding member 150 may be improved.

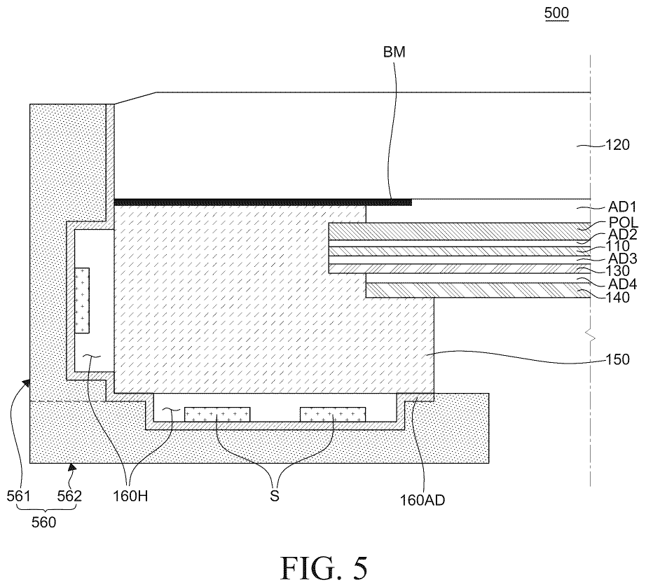

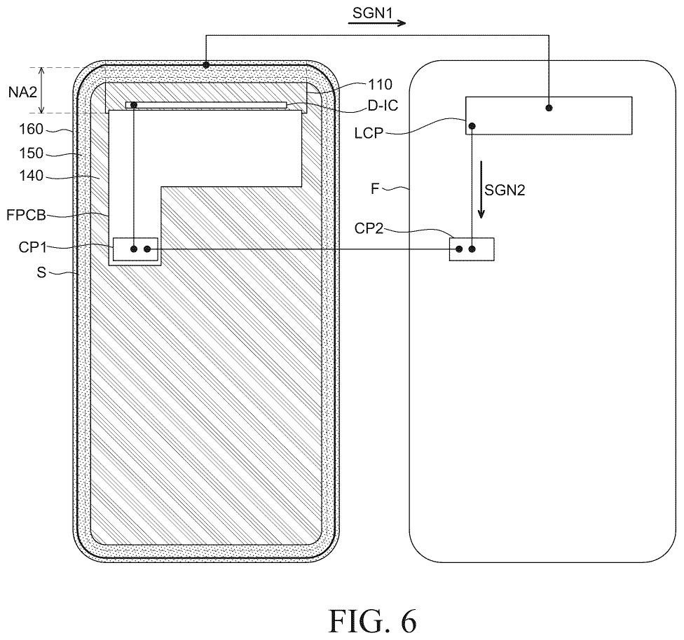

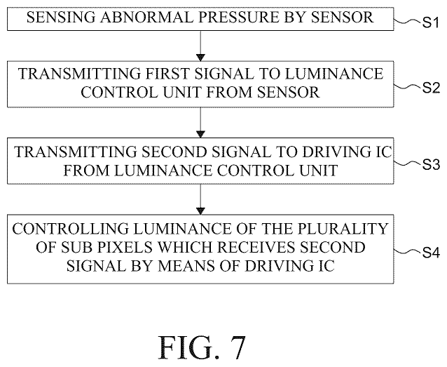

FIG. 5 is a cross-sectional view of a display device according to still another exemplary embodiment of the present disclosure. FIG. 6 is a view for explaining connection of a display panel and a frame of a display device according to still another exemplary embodiment of the present disclosure. FIG. 7 is a flowchart for explaining a luminance compensating method of a display device according to still another exemplary embodiment of the present disclosure. A display device 500 of FIGS. 5 to 7 is the same as the display device 100 of FIGS. 1A to 3 except that a sensor S is disposed in a groove 160H and a frame F and a luminance control unit LCP (e.g., a circuit) are further provided so that a redundant description will be omitted.

Referring to FIGS. 5 and 6, a display device 500 according to still another exemplary embodiment of the present disclosure further includes a sensor S, a frame F, and a luminance control unit LCP.

Referring to FIG. 5, the sensor S is disposed in the groove 160H of the housing 560. The sensor S is disposed on the inner surface of the groove 160H. The sensor S is disposed on the inner surface of the groove 160H to be opposite to the molding member 150 to sense expansion of a volume of the molding member 150. When the sensor S is in contact with the molding member 150 due to the expansion of the molding member 150, the sensor S may transmit a first signal SGN1 to the luminance control unit LCP. At this time, the first signal SGN1 may be a pressure sensitive signal. The sensor S may be a pressure-sensitive sensor which senses a pressure generated by the expansion of the volume of the molding member 150, but is not limited thereto.

Referring to FIG. 5, the sensor S may be disposed in the groove 160H in each of the first part 561 and the second part 562. That is, the sensor S may be disposed so as to opposite to a side surface and a bottom surface of the molding member 150. Therefore, the sensor S may be configured to sense a pressure change according to the expansion of the molding member 150 for all the cases when the molding member 150 expands toward a side portion or expands to the bottom, but it is not limited thereto.

Referring to FIG. 6, the sensor S may be disposed along an outer periphery of the display device 100 along an inner surface of the groove 160H. For example, one sensor S may be disposed for every edge of the display device 100 at the outer periphery of the display device 100 and the sensor S disposed at each edge is connected to a separate wiring line to sense pressures in different positions, but is not limited thereto.

For example, the sensor S extends by means of a wiring line in the groove 160H and may be electrically connected to the flexible circuit board FPCB by means of a cable in a portion adjacent to the flexible circuit board FPCB. Therefore, the sensor S may be electrically connected to the luminance control unit LCP by means of the flexible circuit board FPCB, but is not limited thereto.

Referring to FIG. 6, the frame F may be connected to rear surfaces of the display panel 110 and the back plate 140. The frame F may seal and protect the rear surfaces of the display panel 110 and the back plate 140. In the frame F, various components for driving the display device 600, for example, a camera, a battery, or a sensor, may be disposed. For example, the frame F may be attached to the housing 660 on the rear surfaces of the display panel 110 and the back plate 140 or directly attached to the rear surfaces of the display panel 110 and the back plate 140, but is not limited thereto.

Referring to FIG. 6, a second connection unit CP2 which electrically connects a component of the frame F and the display panel 110 is disposed in the frame F. The second connection unit CP2 may be connected to the first connection unit CP1 disposed on the flexible circuit board FPCB. The component of the frame F and the display panel 110 may be electrically connected by the flexible circuit board FPCB, the first connection unit CP1, and the second connection unit CP2. The second connection unit CP2 may have a shape corresponding to the first connection unit CP1, but is not limited thereto.

Referring to FIG. 6, in the frame F, the luminance control unit LCP which controls a luminance of the display panel 110 may be disposed. The luminance control unit LCP is configured to receive a first signal SGN1 from the sensor S disposed in the groove 160H and transmit a second signal SGN2 to a driving IC D-IC and the plurality of sub pixels SP. The luminance control unit LCP may be configured to control the luminance of the plurality of sub pixels SP when the molding member 150 expands. When the molding member 150 expands, if the first signal SGN1 which is an abnormal pressure sensing signal sensed from the sensor S is transmitted to the luminance control unit LCP, the luminance control unit LCP may transmit the second signal SGN2 which is a luminance control signal to control the luminance of the plurality of sub pixels SP to the plurality of sub pixels SP. However, an operating process of the luminance control unit LCP will be described in detail below with reference to FIG. 7.

The luminance control unit LCP may be electrically connected to the second connection unit CP2 in the frame F. For example, the luminance control unit LCP may be electrically connected to the second connection unit CP2 through a circuit line of the printed circuit board disposed in the frame F. Therefore, the luminance control unit LCP may be electrically connected to the driving IC D-IC and the sensor S by means of the second connection unit CP2, the first connection unit CP1, and the flexible circuit board FPCB. That is, the luminance control unit LCP is connected to the driving IC D-IC by means of the second connection unit CP2, the first connection unit CP1, and the flexible circuit board FPCB to receive the first signal SGN1 from the sensor S and transmit the second signal SGN2 to the driving IC D-IC and the plurality of sub pixels SP. At this time, in the flexible circuit board FPCB and the frame F, the first signal SGN1 and the second signal SGN2 may be transmitted by different signal lines.

Hereinafter, an operating process of the luminance control unit LCP will be described in detail with reference to FIG. 7.

Referring to FIG. 7, a process of operating the luminance control unit LCP to control the luminance of the plurality of sub pixels SP may include a step S1 of sensing an abnormal pressure by a sensor, a step S2 of transmitting a first signal to the luminance control unit from the sensor, a step S3 of transmitting a second signal to the driving IC from the luminance control unit, and a step S4 of controlling a luminance of the plurality of sub pixels which receives the second signal by means of the driving IC.

First, the step S1 of sensing an abnormal pressure by a sensor may be performed by a process of sensing a pressure which is equal to or higher than a predetermined threshold value, by the sensor S, by a pressure generated by the contact of the sensor S and the molding member 150 when the molding member 150 expands. That is, when the volume of the molding member 150 expands due to the temperature increase so that the molding member 150 pressurizes the sensor S with a pressure which is equal to or higher than a predetermined threshold value, the sensor S may sense that an abnormal pressure is generated due to the expansion of the molding member 150.

Next, the step S2 of transmitting a first signal to the luminance control unit from the sensor may be performed by a process of transmitting the first signal SGN1 to the luminance control unit LCP by the sensor S which senses that the abnormal pressure is generated due to the expansion of the molding member 150. For example, the sensor S extends by means of a wiring line in the groove 160H and may be electrically connected to the flexible circuit board FPCB by means of a cable in a portion adjacent to the flexible circuit board FPCB. Therefore, the sensor S may be electrically connected to the luminance control unit LCP by means of the flexible circuit board FPCB, but is not limited thereto.

Next, in the step S3 of transmitting a second signal to the driving IC from the luminance control unit may be performed by a process of transmitting the second signal SGN2 output through, for example, a feedback circuit to the plurality of sub pixels SP, by the luminance control unit LCP which receives the first signal SGN1 to perceive the abnormal pressure. At this time, the second signal SGN2 may be a luminance control signal which reduces a luminance of the plurality of sub pixels SP. For example, the luminance control unit LCP is connected to the driving IC D-IC by means of the second connection unit CP2, the first connection unit CP1, and the flexible circuit board FPCB to transmit the second signal SGN2 to the driving IC D-IC and the plurality of sub pixels SP.

Finally, in the step S4 of controlling a luminance of the plurality of sub pixels which receives the second signal by means of the driving IC may be performed by a process of changing a data voltage in the plurality of sub pixels SP which receives the second signal from the luminance control unit LCP and the driving IC D-IC and controlling the luminance of the plurality of sub pixels SP. At this time, the luminance of the plurality of sub pixels SP may be reduced by the second signal SGN2. In the meantime, after reducing the luminance of the plurality of sub pixels SP by the second signal SGN2, when the second signal SGN2 which is transmitted to the plurality of sub pixels SP is released, the data voltage of the plurality of sub pixels SP is restored so that the luminance of the plurality of sub pixels SP increases again. However, it is not limited thereto.

At this time, in the display device, a volume of the molding member which is formed of resin expands as the temperature increases. When the molding member expands, the molding member disposed in the housing pressurizes the side surface of the display panel to cause cracks in various insulating layers of the display panel. At this time, moisture permeates various components of the display panel by the cracks of the insulating layer, which causes erroneous operations. For example, in a light emitting diode or a circuit element of the plurality of sub pixels, erroneous operations such as abnormal luminance increase or abnormal heat generation may be caused. Further, the abnormal luminance may increase, or abnormal heat generation may cause the damage of components of the display panel.

The display device 500 according to still another exemplary embodiment of the present disclosure includes a luminance control unit SCP which is configured to control the luminance of the plurality of sub pixels SP when an abnormal pressure is sensed from the sensor S disposed in the groove 160H, to improve the reliability of the display device 500.

Specifically, in the display device 500 according to still another exemplary embodiment of the present disclosure, the sensor S is disposed on the inner surface of the groove 160H of the housing 560 to be opposite to the molding member 150. When the sensor S senses an abnormal pressure which is equal to or higher than a predetermined threshold value by the contact with the molding member 150 due to the expansion of the molding member 150, the sensor S transmits a first signal SGN1 to the luminance control unit LCP. Further, when the luminance control unit LCP receives the first signal SGN1 from the sensor S, the luminance control unit LCP transmits the second signal SGN2 for controlling the luminance of the plurality of sub pixels SP to the plurality of sub pixels SP. In the plurality of sub pixels SP which receives the second signal SGN2, the data voltage is changed to reduce the luminance. When the molding member 150 expands to cause an abnormal pressure in the housing 560, the sensor S is configured to sense the abnormal pressure and the luminance control unit LCP may be configured to reduce the luminance of the plurality of sub pixels SP. That is, the plurality of sub pixels SP may be configured to reduce the luminance when the abnormal pressure is generated. Therefore, when the insulating layer of the display panel 110 is cracked by the abnormal pressure, the luminance of the plurality of sub pixels SP is reduced and the heat generated in the light emitting diode and the circuit elements disposed in the plurality of sub pixels SP may be minimized. By doing this, even though the components to which the moisture permeates due to the crack of the insulating layer erroneously operate, the heat generation is minimized so that the damage of the components of the display panel 110 caused by the abnormal heat generation may be minimized and the reliability of the display device 500 may be improved.

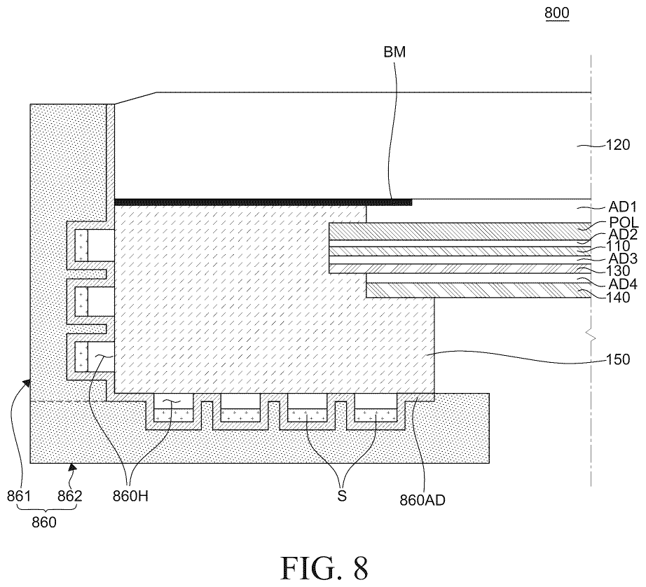

FIG. 8 is a cross-sectional view of a display device according to still another exemplary embodiment of the present disclosure. A display device 800 of FIG. 8 is the same as the display device 500 of FIGS. 5 to 7 except that a plurality of grooves 860H are disposed in a housing 860 so that a redundant description will be omitted.

Referring to FIG. 8, in a display device 800 according to still another exemplary embodiment of the present disclosure, a plurality of grooves 860H are disposed in the housing 860. At this time, a plurality of grooves 860H are disposed in each of a first part 861 and a second part 862 of the housing 860. In the meantime, even though in FIG. 8, it is illustrated that three grooves 860H are disposed in the first part 861 and four grooves 860H are disposed in the second part 862, the number of grooves 860H disposed in each of the first part 861 and the second part 862 may vary depending on the design, but is not limited thereto.

Referring to FIG. 8, the inner surface of the housing 860 in which the groove 860H is not disposed is disposed to be in contact with the molding member 150. For example, the part of the inner surface of the housing 860 in which the groove 860H is disposed is spaced apart from the molding member 150 and a part of the inner surface of the housing 860 in which the groove 860H is not disposed may be bonded to the molding member 150 by means of the housing adhesive layer 860AD.

In the display device 800 according to another exemplary embodiment of the present disclosure, a plurality of grooves 860H are disposed in the housing 860 so that the adhesive strength between the housing 860 and the molding member 150 may be improved.

Specifically, in the display device 800 according to still another exemplary embodiment of the present disclosure, a plurality of grooves 860H are disposed in the housing 860. A plurality of grooves 860H are disposed in each of a first part 861 and a second part 862 of the housing 860. In the meantime, the part of the inner surface of the housing 860 in which the groove 860H is disposed is spaced apart from the molding member 150 and the part of the inner surface of the housing 860 in which the groove 860H is not disposed, for example, an inner surface of the housing 860 corresponding to an area between the plurality of grooves 860H, may be bonded to the molding member 150 by means of the housing adhesive layer 860AD. At this time, when the number of grooves 860H increases, the area of the inner surface of the housing 860 corresponding to an area between the plurality of grooves 860H is relatively increased, as compared with the smaller number of grooves 860H. That is, when the plurality of grooves 860H are disposed in the housing 860, an area of the inner surface of the housing 860 corresponding to an area between the plurality of grooves 860H may be increased. Therefore, an area of the inner surface of the housing 860 attached to the molding member 150 by the housing adhesive layer 860AD is increased and the adhesive strength between the housing 860 and the molding member 150 may be improved. Accordingly, in the display device 800 according to another exemplary embodiment of the present disclosure, a plurality of grooves 860H are disposed in the housing 860 so that the adhesive strength between the housing 860 and the molding member 150 may be improved.

In the meantime, in the display device 800 according to still another exemplary embodiment of the present disclosure, a sensor S is disposed in each of the plurality of grooves 860H so that the precision for the pressure sensing function of the sensor S may be improved. For example, an expansion degree of the molding member 150 which is formed of resin may be partially different, but the sensor S is disposed in each of the plurality of grooves 860H of the housing 860. Therefore, at least a part of the sensors S disposed in different positions may sense the pressure change in accordance with the expansion of the molding member 150. Therefore, even though the molding member 150 partially differently expands, the sensors S disposed in different positions sense the pressure change according to the expansion of the molding member 150 so that the precision for the pressure sensing function of the sensor S may be improved.

The exemplary embodiments of the present disclosure can also be described as follows:

According to an aspect of the present disclosure, a display device includes a cover window, a display panel which includes an active area disposed below the cover window and including a plurality of pixels disposed therein, a first non-active area which encloses the active area, and a bending area which extends from one side of the first non-active area to be bent, a housing which encloses a side surface of the cover window and is spaced apart from the display panel to extend to the bottom of the display panel and a molding member which is disposed in a space in which the housing and the display panel are spaced apart from each other, below the cover window. The molding member is disposed so as to cover a side surface of the display panel and the housing includes a groove disposed in an inner surface opposite to the molding member.

A part of the inner surface of the housing may be bonded to the molding member.

The housing may include a first part which extends downwardly from a side surface of the cover window, and a second part which extends inwardly from an end portion of the first part.

The groove may be disposed in each of the first part and the second part.

A plurality of grooves may be disposed in each of the first part and the second part.

The display device may further comprise a sensor which is disposed on an inner surface of the groove to be opposite to the molding member.

The display device may further comprise a flexible circuit board which is connected to the display panel and is disposed below the display panel, and a luminance control unit which is connected to the flexible circuit board.

The sensor may transmit a first signal to the luminance control unit when the sensor is in contact with the molding member.

The display device may further comprise a plurality of sub pixels which is disposed in the active area on the display panel.

When the first signal is transmitted from the sensor, the luminance control unit may transmit a second signal to the plurality of sub pixels.

A luminance of the plurality of sub pixels may be reduced by the second signal.

The display panel may further include a second non-active area which extends from the bending area to be disposed below the active area and is connected to the flexible circuit board.

The sensor may be a pressure sensitive sensor.

In the groove, the molding member and the housing may be spaced apart from each other.

The molding member may be filled in the groove.

The display device may further comprise a housing adhesive layer which is disposed on an inner surface of the housing and bonds between the cover window and the molding member and the housing.

The display device may further comprise a back plate disposed below the display panel, and a metal plate which is disposed below the back plate.

The molding member may be disposed so as to enclose a side surface of the display panel, a side surface of the back plate, a side surface of the metal plate, and a part of a bottom surface of the metal plate.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a cover window;
a display panel that includes an active area below the cover window and including a plurality of pixels disposed therein, a first non-active area that encloses the active area, and a bending area that extends from one side of the first non-active area and is configured to be bent;
a housing that encloses a side surface of the cover window, the housing spaced apart from the display panel and extends to a bottom of the display panel; and
a molding member in a space in which the housing and the display panel are spaced apart from each other, the molding member below the cover window,
wherein the molding member covers a side surface of the display panel and the housing includes a groove on an inner surface which is opposite to the molding member.

2. The display device according to claim 1, wherein a part of the inner surface of the housing is bonded to the molding member.

3. The display device according to claim 1, wherein the housing includes:
a first part that extends downwardly from a side surface of the cover window; and
a second part that extends inwardly from an end portion of the first part, and
the groove is in each of the first part and the second part.

4. The display device according to claim 3, wherein a plurality of grooves are in each of the first part and the second part.

5. The display device according to claim 1, further comprising:
a sensor on an inner surface of the groove, the sensor opposite to the molding member.

6. The display device according to claim 5, further comprising:
a flexible circuit board that is connected to the display panel, the flexible circuit board below the display panel; and
a luminance control circuit that is connected to the flexible circuit board,
wherein the sensor transmits a first signal to the luminance control circuit when the sensor is in contact with the molding member.

7. The display device according to claim 6, further comprising:
a plurality of sub pixels in the active area on the display panel,
wherein when the first signal is transmitted from the sensor, the luminance control circuit transmits a second signal to the plurality of sub pixels.

8. The display device according to claim 7, wherein a luminance of the plurality of sub pixels is reduced by the second signal.

9. The display device according to claim 6, wherein the display panel further includes a second non-active area that extends from the bending area and is below the active area, the second non-active area connected to the flexible circuit board.

10. The display device according to claim 5, wherein the sensor is a pressure sensitive sensor.

11. The display device according to claim 1, wherein in the groove, the molding member and the housing are spaced apart from each other.

12. The display device according to claim 1, wherein the molding member is filled in the groove.

13. The display device according to claim 1, further comprising:
a housing adhesive layer on an inner surface of the housing and bonds between the cover window and the molding member and the housing.

14. The display device according to claim 1, further comprising:
a back plate below the display panel; and
a metal plate below the back plate,
wherein the molding member encloses a side surface of the display panel, a side surface of the back plate, a side surface of the metal plate, and a part of a bottom surface of the metal plate.
